(19) United States
(12) Patent Application Publication
(10) Pub. No.: US 2010/0288361 A1
(43) Pub. Date: Nov. 18, 2010

(54) THIN-FILM SOLAR CELL AND PROCESS FOR PRODUCING A THIN-FILM SOLAR CELL

(76) Inventors: Eveline Rudigier-Voigt, Mainz (DE); Burkhart Speit, Mainz (DE); Wolfgang Mannstadt, Muenster-Sarmsheim (DE); Silke Wolff, Hueckeswagen (DE)

Correspondence Address: MICHAEL J. STRIKER, 103 EAST NECK ROAD, HUNTINGTON, NY, 11743, US

(21) Appl. No.: 12/775,534

(22) Filed: May 7, 2010

(30) Foreign Application Priority Data
May 12, 2009 (DE) 10 2009 020 954.9
Oct. 28, 2009 (DE) 10 2009 050 987.9

(51) Int. Cl. H01L 31/00; H01L 31/18

(52) U.S. Cl. 136/261; 136/252; 438/95; 257/E31.027

(57) ABSTRACT

The thin-film solar cell includes at least one Na₂O-containing multicomponent substrate glass, which is not phase demixed and has a content of β-OH of from 25 to 89 mmol/l. The process for making a thin-film solar cell includes the following steps:
a) providing an Na₂O-containing multicomponent substrate glass, which has a content of β-OH of from 25 to 80 mmol/l and is not phase demixed;
b) applying a metal layer to the substrate glass, which forms an electrical back contact of the thin-film solar cell;
c) applying an intrinsically p-conducting polycrystalline layer of a compound semiconductor material, in particular a CIGS compound semiconductor material, which includes at least one high-temperature step at a temperature of >550° C.; and
d) applying a p/n junction.

### CROSS-REFERENCE

The inventions described and claimed herein below are also described in German Patent Application No. 10 2009 020 954.9, filed on May 12, 2009 in Germany, and German Patent Application No. 10 2009 050 987.9, filed on Oct. 28, 2009 in Germany. These German Patent Applications provide the basis for respective claims of priority of invention for the thin-film solar cell and process claimed herein below under 35 U.S.C. 119 (a)-(d).

### BACKGROUND OF THE INVENTION

1. The Field of the Invention

The invention relates to a thin-film solar cell and a process for producing a thin-film solar cell.

2. The Description of the Related Art

Thin-film technology is today competing strongly with the established c-Si wafer technology in photovoltaics. Large-area deposition processes at usually low efficiencies make this technology attractive in terms of production costs and thus the ε/Wp. An advantage of thin-film technology is a comparatively short value added chain, since semiconductor cell and module production can be carried out in an integrated fashion. Nevertheless, cost reduction measures are playing an ever increasing role for thin-film technology in photovoltaics.

The cost reduction potentials are, in particular, in a reduction in materials consumption, shortening of the process times and, associated therewith, a higher throughput and also an increase in the yield. Solar cell concepts based on thin films rely in particular on coating technologies for a large area. A big challenge is homogeneous coating of large areas (>1 m²), in particular edge effects or inhomogeneous ion exchange effects from, for example, the glass substrate locally influence the quality of the layers produced, which shows up macroscopically in a reduction of the yield but also the energy conversion efficiency of the module.

Thin-film solar cells based on compound semiconductors, for example CdTe or CIGS (of the general formula Cu(In₁₋ₓ, Gaₓ)(S_{1-y}, Se_{y})₂) display excellent stability and also very high energy conversion efficiencies; such a solar cell structure is known, for example, from U.S. Pat. No. 5,141,564. These materials are characterized, in particular, by being direct semiconductors and absorbing sunlight effectively even in a relatively thin layer (about 2 μm). The deposition technologies for such thin photoactive layers require high processing temperatures in order to achieve high efficiencies. Typical temperature ranges are from 450 to 600° C., with the maximum temperature being limited, in particular, by the substrate. For large-area applications, glass is generally used as substrate. Owing to economic considerations, i.e. low costs, and a coefficient of thermal expansion (CTE) which is approximately matched to the semiconductor layers, soda-lime glass produced by the float process (window glass) is used as substrate, as is disclosed in DE 43 33 407, WO 94/07269. Soda-lime glass has a glass transition temperature of about 555° C. and therefore limits all subsequent processes to about 525° C. since otherwise “sagging” occurs and the glass sheet begins to bend. This applies all the more the larger the substrate to be coated and the closer the process temperature is to the glass transition temperature (Tg) of the glass. Sagging or bending leads, particularly in in-line processes/plants, to problems, for example at the locks, and as a result the throughput and/or the yield becomes poorer.

Higher temperatures, viz. >550° C., can be achieved, for example, on metal foils, e.g. Ti foil, which withstand these temperatures, as described in WO 2005/006393. However, such systems have the disadvantage that they are not suitable for a monolithic integrated arrangement of the modules in series because of their inherent conductivity and coating on a large area proves to be extremely difficult because of the flexibility of the substrates. Solar cells on metal foil are, inter alia, connected in series. Owing to the low weight, such modules are particularly suitable for extraterrestrial applications. Glass substrates are in principle preferable for terrestrial applications; apart from the static properties and the easier processing, especially also because of the significantly higher efficiencies which can be achieved.

It is generally known that an improvement in the electrical properties of such thin-film solar cells based on compound semiconductors can be achieved when these are deposited at high temperatures, i.e. >550° C. In detail, this means that if a deposition process of such thin compound semiconductor layers were successful at high temperatures, then these layers could be optimized with regard to processing, i.e. higher deposition and cooling rates, and also in terms of their performance as a photovoltaic component, i.e. an excellent crystalline quality. As mentioned above, soda-lime glass is not suitable for this purpose.

DE 100 05 088 and JP 11-135819 A describe glass substrates for thin-film photovoltaic modules based on compound semiconductors. In DE 100 05 088, the CTE was matched to the CTE of the first layer, the back contact (for example of molybdenum). On such substrates, a CTE mismatch between glass substrate and CIGS semiconductor layer means that adhesion of the CIGS layer to the Mo-coated glass substrate is not ensured. In addition, these substrates contain boron which, particularly at high temperatures, i.e. >550° C., can be given off as gas from the substrate and acts as semiconductor poison in the CIGS. It will be desirable to have a substrate which can contain boron but cannot give the latter off as gas and therefore does not interfere in the deposition process and thus adversely affect the semiconductor layer.

JP 11-135819 A describes substrates which do not have a CTE mismatch. However, these glasses contain a high proportion of alkaline earth metal ions, which leads to the mobility of the alkali metal ions in the substrate being drastically reduced or prevented. It is generally known that alkali metal ions play an important role during deposition of the thin films of compound semiconductors and it is therefore desirable to have a substrate for the deposition process which allows a release of alkali metal ions which is homogeneous both in terms of physical location and also time. In addition, this alkali metal ion mobility is further restricted by the unfavorable molar ratio of SiO₂/Al₂O₃>8. Such glass structures are dominated by the structural element of the Si⁴⁺-oxygen tetrahedron without satisfactory diffusion paths such as the structural element Al³⁺/Na⁺ in the oxygen anion sub-lattice.

DE 196 16 679 C1 and DE 196 16 633 C1 describe a material having a similar glass composition. However, this material can contain arsenic which is a semiconductor poison for these layer systems and, in particular at high temperatures, can be given off as gas and thus contaminate the semiconductor layer. This material is therefore unsuitable as glass substrate for CIGS-based solar cells. Here, it is either necessary to use arsenic-free substrates as a result of alternative refining agents, to prevent outgassing of arsenic by means of applied barrier layers or to inhibit outgassing by means of targeted modification of the glass substrate.

Furthermore, it is known that sodium has a positive effect on the crystallite structure and crystal density and also on the crystallite size and orientation. Various approaches for this purpose have been discussed among persons skilled in the art; significant aspects are improved chalcogen incorporation into the crystal lattice and the passivation of grain boundaries. These phenomena automatically lead to considerably better semiconductor properties, in particular to a reduction in recombination in the bulk material and thus to a higher open-circuit potential. This then results in a higher efficiency.

However, the release of alkali metal ions from the substrate into the semiconductor layer is very inhomogeneous both in terms of location and in particular time when soda-lime glasses are used.

In WO 94/07269, this problem is solved by a barrier layer (usually SiₓN_{y}, SiOₙN_{y} or Al₂O₃) applied to the glass surface before coating with the back contact so as to block the diffusion of sodium from the glass into the semiconductor layer. Sodium is then separately added as layer on the barrier layer or on the back contact layer (often in the form of NaF₂) in a further process step, which, however, significantly increases process times and costs.

Thin polycrystalline layers/packets of layers based on Cu(In₁₋ₓ, Gaₓ)—(S_{1-y}, Se_{y})₂ can in principle be produced by a series of processes including co-vaporization and the sequential process. In addition, processes such as liquid coating or electroplating combined with a heating step in a chalcogen atmosphere are also suitable. One deposition method which is particularly suitable for large areas and compared to others has a relatively stable processing window is the sequential process. This process allows relatively short processing times in the region of a few minutes; the limiting factor here is the cooling of the substrate and the process thus promises good economics. In addition, the process is based on furnace processes which are known, in particular, from thick-film doping of silicon for photovoltaics and makes comparatively simple process control possible (US 2004/115938). In this process, a molybdenum layer which has the function of the back contact is firstly applied to the substrate. A metallic precursor layer comprising Cu, In and/or Ga is then applied, for example by sputtering, and is subsequently reacted thermally in a chalcogen atmosphere at temperatures of at least 500° C. In this last process step, the rear side of the glass substrate can also be attacked. For example, the SO₂ or SeO₂ in the sulphur or selenium vapor can react with the sodium ions in the soda-lime glass surface to form water-soluble Na₂SO₄ or Na₂SeO₄, as a result of which the glass surface can be significantly damaged. In addition, cracks can occur in the layer structure, for example as a result of heat inhomogeneities in the packet of layers during the coating process, spatially inhomogeneous diffusion of the alkali metal ions from the glass into the layer or generation of mechanical stresses in the glass in the case of excessively rapid cooling. Particularly in respect of the temperature profile, the scale-up from the laboratory scale (10×10 cm²) to the industrial scale (at present 125×65 cm²) has not been mastered completely.

A further disadvantage of this deposition method is that detachment of the absorber layer from the back contact layer is frequently observed and can lead to a poor yield during solar cell production, in particular in the case of exterior applications as a result of temperature change stresses between day/night or between seasons. It is known from U.S. Pat. No. 4,915,745 or DE 43 33 407 that improved bonding can be achieved by means of intermediate layers. However, it would be desirable to dispense with such an additional process step.

Corrosion resistance is a central issue for thin-film solar cells in general and for solar cells based on CIGS semiconductors in particular. Corrosion-triggering processes can be: the handling of the glass specimens, exterior weathering, in particular in respect of long-term stability requirements (up to 20 years), and the CIGS deposition process itself, since such corrosion effects increase, in particular, when the substrate is exposed to high temperatures in an S/Se-containing atmosphere.

### SUMMARY OF THE INVENTION

It is therefore an object of the invention to provide a thin-film solar cell which is improved compared to the prior art. A further object of the invention is to provide a process which is improved compared to the prior art for producing a thin-film solar cell. The solar cell of the invention should be able to be produced economically by known processes or by the process of the invention and have a higher efficiency.

A further object of the present invention is to provide a process for producing a highly efficient thin-film solar cell on a highly corrosion-stable, heat-resistant and functional substrate glass, where the semiconductor deposition process should comprise at least one high-temperature step, i.e. at a temperature of >550° C.

Furthermore the invention is required to overcome:
the temperature limitation due to the glass substrate while simultaneously matching the CTE to the layer system,
thermally induced substrate glass distortion, particularly in the case of flat modules, which occurs in the case of soda-lime substrate glass processed at high temperatures,
semiconductor poisons which can be incorporated into the semiconductor layer during the deposition process at high temperatures, as is the case for glass substrates corresponding to the prior art DE 100 05 088, DE 196 16 679, DE 196 16 633,
the inhomogeneous alkali metal ion introduction into the semiconductor layer in terms of physical location and time during the deposition process without additional process steps, in contrast to WO 94/07269,
the thickness limitation of the glass substrate due to unsatisfactory stiffness of the glass substrate itself and also the process conditions during deposition,
corrosion problems,
adhesion problems,
inhomogeneities during crystal growth itself,
the processing time limitation, in particular in the cooling operation but also more rapid deposition process (throughput),
insufficiently high efficiencies,
low yields.

This object is achieved by the thin-film solar cell as defined in the appended claims, which comprises at least one Na₂O-containing multicomponent substrate glass, wherein the substrate glass is not phase demixed and has a content of β-OH of from 25 to 80 mmol/l.

Furthermore, it has been found that it is advantageous for the substrate glass of the solar cell of the invention to have
a glass transition temperature Tg of greater than 550° C., in particular greater than 600° C., and/or
a coefficient of thermal expansion α_{20/300} of greater than 7.5×10⁻⁶/K, in particular from 8.0×10⁻⁶/K to 9.5×10⁻⁶/K, in the temperature range from 20° C. to 300° C., and/or
to contain less than 1% by weight of B₂O₃, less than 1% by weight of BaO and less than a total of 3% by weight of CaO+SrO+ZnO (total of CaO+SrO+ZnO<3% by weight), and/or
to have a molar ratio of the substrate glass components (Na₂O+K₂O)/(MgO+CaO+SrO+BaO) of greater than 0.95, and/or
a molar ratio of the substrate glass components SiO₂/Al₂O₃ of less than 8.8, in particular less than 7.

It is particularly advantageous for all the above-mentioned features to be present.

Furthermore, it has been found that the solar cell can be a planar, curved, spherical, or cylindrical thin-film solar cell. The solar cell of the invention is preferably an essentially planar (flat) solar cell or an essentially tubular solar cell, with flat substrate glasses or tubular substrate glasses preferably being used. The solar cell of the invention is in principle not subject to any restriction in respect of its shape or the shape of the substrate glass. In the case of a tubular solar cell, the external diameter of a tubular substrate glass of the solar cell is preferably from 5 to 100 mm and the wall thickness of the tubular substrate glass is preferably from 0.5 to 10 mm.

As regards the process, the object is achieved by the process claimed in the process claims appended herein below. The process according to the invention for producing a thin-film solar cell, in particular a solar cell according to the solar cell claims appended herein below, comprises at least the following steps:

a) providing an Na₂O-containing multicomponent substrate glass, which has a content of β-OH of from 25 to 80 mmol/l and is not phase demixed;

b) applying a metal layer to the substrate glass, which forms an electrical back contact of the thin-film solar cell;

c) applying an intrinsically p-conducting polycrystalline layer of a compound semiconductor material, in particular a CIGS compound semiconductor material, which includes at least one high-temperature step at a temperature of >550° C.; and

d) applying a p/n junction, in particular via a combination of a buffer layer and a subsequent window layer.

In the case of a series arrangement which is not monolithically integrated, a metallic front side contact is preferably applied.

The term “metal layer” here encompasses all suitable, electrically conductive layers.

The solar cells of the invention and the solar cells produced by the process of the invention have an over 2% absolute higher efficiency compared to the prior art.

Step b) preferably comprises applying a metal layer to the substrate glass, with the metal layer forming an electrical back contact of the thin-film solar cells, which is a single-layer or multilayer system composed of suitable materials, particularly preferably a single-layer system composed of molybdenum.

Step c) preferably comprises applying an intrinsically p-conducting polycrystalline layer of a compound semiconductor material, particularly preferably a material based on CIGS, with at least one high-temperature step in the temperature range 550° C.<T<700° C., particularly preferably 600° C.<T<700° C.

Step d) preferably comprises applying an intrinsically n-conducting buffer layer of a semiconductor material, particularly preferably CdS, In(OH), InS or the like, and a window layer composed of a transparent conductive material, particularly preferably ZnO:Al, ZnO:Ga or SnO:F. This window layer comprises an intrinsic layer and a highly doped layer.

A substrate glass is not phase demixed for the purposes of the present invention when it has fewer than 10, preferably fewer than 5, surface defects in a surface region of 100×100 nm² after a conditioning experiment. The conditioning experiment was carried out as follows:

The substrate glass surface to be examined is subjected at 500-600° C. to a flow of compressed air in the range from 15 to 50 ml/min and a flow of sulphur dioxide gas (SO₂) in the range from 5 to 25 ml/min for a time of from 5 to 20 minutes. Regardless of the type of glass, this results in formation of a crystalline coating on the substrate glass. After washing off the crystalline coating (e.g. by means of water or an acidic or basic aqueous solution so that the surface is not attacked further), the surface defects per unit area of the substrate glass surface are determined by microscopy. If fewer than 10, in particular fewer than 5, surface defects are present in a surface region of 100×100 nm², the substrate glass is considered not to be phase demixed. All surface defects having a diameter of >5 nm are counted.

The β-OH content of the substrate glass was determined as follows. The apparatus used for the quantitative determination of water via the OH stretching vibration at 2700 nm is the commercial Nicolet FTIR spectrometer with attached computer evaluation. The absorption in the wavelength range 2500-6500 nm was firstly measured and the absorption maximum at 2700 nm was determined. The absorption coefficient α was then calculated from the specimen thickness d, the pure transmission Tᵢ and the reflection factor P:

α=1/d*Ig(1/Tᵢ)[cm⁻¹], where Tᵢ=T/P with the transmission T.

Furthermore, the water content is calculated from c=α/e,

where e is the practical extinction coefficient [I*mol⁻¹*cm⁻¹] and for the above-mentioned evaluation range is used as a constant value of e=110 l*mol⁻¹*cm⁻¹ based on mol of H₂O. The e value is taken from the work by H. Frank and H. Scholze in “Glastechnischen Berichten”, Volume 36, No. 9, page 350.

In this text, a thin-film solar cell will in the interests of simplicity be referred to as solar cell for short, even in the dependent claims. For the purposes of the present patent application, the term “substrate glass” can also encompass a superstrate glass.

For the purposes of the present invention, the expression Na₂O-containing multicomponent substrate glass means that the substrate glass can contain, in addition to Na₂O, further composition components such as B₂O₃, BaO, CaO, SrO, ZnO, K₂O, MgO, SiO₂ and Al₂O₃, and also nonoxidic components such as F, P, N.

The present invention makes it possible to develop an inexpensive, highly efficient monolithically integrated photovoltaic module based on compound semiconductors such as CdTe or CIGS. For the purposes of the invention, the term inexpensive refers to very low ε/watt costs, especially as a result of higher efficiencies, faster processing times and thus a higher throughput and also higher yields.

The invention encompasses a substrate glass which has, apart from its support function, an active role in the semiconductor production process and displays in particular due to optimal CTE matching at high temperatures to the photoactive thin compound semiconductor layer, both a high thermal stability (i.e. a high stiffness) and chemical stability (i.e. a high corrosion resistance).

The invention encompasses tandem, multi-junction or hybrid thin-film solar modules from a high-temperature process deposited on a substrate glass, and also a process for producing such modules. Furthermore, the solar module can, according to the invention, have flat, spherical, cylindrical or other geometric shapes. In a particular embodiment, the glass can be colored.

Preferred technical features of the substrate glass provided by the invention are: (i) highly corrosion resistant, (ii) material without physical phase separation, (iii) As-, B-free, (iv) high-temperature stable, (v) matched coefficient of thermal expansion (CTE), (vi) Na content, (vii) mobility of Na in the glass, (viii) stiffness (SP-Tg)≧200° C.

Preferred technical features of the process: (i) large-area process, (ii) high temperatures (>550° C., in particular >600° C.), (iii) more homogeneous process, i.e. faster processing times and thus higher throughput, and (iv) higher yield.

The process of the invention for producing a thin-film solar cell preferably comprises at least one or all of the following steps:
a) provision of a substrate which fulfils the required conditions, purification and preconditioning of the substrate glass by acid leaching of surface impurities and sodium ions close to the surface in hydrochloric acid-containing washing lotion,
b) formation of a metal layer on the substrate, with the metal layer forming an electrical back contact in the thin-film solar cells, which is preferably a single-layer system without structural steps or fractures,
c) formation of an intrinsically p-conducting polycrystalline layer of a compound semiconductor material, particularly preferably a material based on CIGS, with at least one high-temperature step,
d) formation of a p/n junction by introduction of a thin buffer layer, for example a CdS layer having a thickness of a few nm, and subsequently a n-con-ducting, transparent TCO, for example ZnO or ZnO:Al or a combination thereof,
e) formation of a monolithic series arrangement between the various deposition steps or application of a front contact grid comprising metal fingers and current collection tracks, and
f) encapsulation of the thin-film module.

Aluminosilicate glass systems having high alkali metal content surprisingly met the requirements for a substrate glass for a thin-film solar cell produced in a high-temperature process. In a particular example, the high-temperature CIGS production technology in which substrate glass temperatures are up to 700° C. could be employed, with the CTE of the substrate at the same time being matched to the CIGS semiconductor layer. In this way, 2% higher efficiencies of CIGS cells compared to the standard process at temperatures of ˜525° C. could be achieved.

The requirements which the glass substrate has to meet for a production process comprising a high-temperature step are fulfilled particularly well by glass compositions (mol %) in the following range:

| | |
|---|---|
| SiO₂ | 61-70.5 |
| Al₂O₃ | 8.0-15.0 |
| B₂O₃ | 0-4.0 |
| Na₂O | 0.5-18.0 |
| K₂O | 0.05-10.0 |
| Li₂O + Na₂O + K₂O | 10.0-22.0 |
| MgO | 0-7.0 |
| CaO | 0-5.0 |
| SrO | 0-9.0 |
| BaO | 0-5.0 |
| MgO + CaO + SrO + BaO | 0, in particular >0.5, preferably >5 |
| CaO + SrO + BaO + ZnO | 0.5-11.0 |
| TiO₂ + ZrO₂ | 0-4.0 |
| SnO₂ + CeO₂ | 0-0.5, in particular 0.01-0.5, |
| | preferably 0.1-0.5 |
| As₂O₃ + Sb₂O₃ + P₂O₅ + La₂O₃ | 0-2.0 |
| F₂ + Cl₂ | 0-2, in particular 0-1.0 |
| β-OH, mmol/litre | 25-80 |
| SiO₂/Al₂O₃ | 4.2-8.8 |
| Alkali metal oxides/Al₂O₃ | 0.6-3.0 |
| Alkaline earth metal | 0.1-1.3 |
| oxides/Al₂O₃ | |
| Number of surface defects | <10 |

The glasses were melted from conventional raw materials in 4 litre platinum crucibles. To ensure a certain amount of water in the glass, the Al raw material Al(OH)₃ was used and, in addition, an oxygen burner was employed in the furnace space of the gas-heated melting furnace (oxyfuel technique) to achieve the high melting temperatures under oxidizing melting conditions. The raw materials were introduced at melting temperatures of 1580° C. over a period of 8 hours and subsequently maintained at this temperature for 14 hours. The glass melt was then cooled while stirring to 1400° C. over a period of 8 hours and subsequently poured into a graphite mold which had been preheated to 500° C. This casting mold was introduced immediately after casting into a cooling furnace which had been preheated to 650° C. and cooled to room temperature at 5° C./h. The glass specimens necessary for the measurements were then cut from this block.

It was surprisingly found that these glasses have a high homogeneity in respect of bubble content when melted under oxidizing conditions using nitrates of the alkali metal and/or alkaline earth metal components.

The molar ratios of the two glass formers SiO₂ to Al₂O₃ are responsible for the achievement of high use temperatures of the substrate glasses since they determine the increase in the viscosity in the range from the glass transition temperature (Tg) to the softening point. Such “long” glasses can not only be thermally stressed to the glass transition temperature without deformation but also to about 100° C. below the softening point (SP) of the glasses. Thus, it can be ensured that no thermally induced deformation of the substrate occurs even when it is used at high temperatures i.e. from >550° to <700° C. However, the important requirement of CTE matching to the subsequent layer system has to be achieved at the same time.

The molar ratio of the sum of alkali metal ions to Al₂O₃ is critical, especially for the high coefficient of expansion of boroaluminosilicate glasses. Only the very narrow ratio of alkali metal oxides/aluminium oxide of from 0.6 to 3.0 which has surprisingly been found here meets the two requirements of high Tg in the range from 580 to 680° C. and at the same time a high coefficient of thermal expansion of greater than 7.5×10⁻⁶/K and therefore the required CTE.

In the production of semiconductors, it is generally extremely critical if semiconductor poisons get into the process since these drastically reduce the performance of the layer. In the production of CIGS-based solar cells in the high-temperature process, it is important to prevent semiconductor poisons, such as iron, arsenic or boron, from being given off from the glass as gas or from diffusing out of the glass, since these elements, inter alia, become active recombination sites and can lead to deterioration in open-circuit potential and lead to short circuits.

It has surprisingly been found that the glasses having the above glass compositions precisely meet the requirements of a high-temperature process, since they are iron-free but have a water content of >25 mmol/litre, preferably >40 mmol/litre and particularly preferably >50 mmol/litre. The semiconductor poisons are therefore chemically bound and cannot get into the process, even at temperatures of >550° C.

TABLE I
EXAMPLES OF SUBSTRATE GLASSES USED IN THE SOLAR
CELLS ACCORDING TO THE INVENTION, COMPOSITION IN MOL %, OR
MOLAR RATIOS

| | EXAMPLE | | | | | | |
|---|---|---|---|---|---|---|---|
| | 1 | 2 | 3 | 4 | 5 | 6 | 7 |
| SiO₂ | 64.88 | 68.65 | 66.32 | 63.77 | 66.26 | 66.83 | 70.04 |
| Al₂O₃ | 11.07 | 11.2 | 7.96 | 11.01 | 10.91 | 10.91 | 13.22 |
| B₂O₃ | 0.45 | 3.65 | 0 | 0 | 0 | 0 | 0 |
| Li₂O | 2.49 | 0.49 | 0 | 0 | 0 | 0 | 1.06 |
| Na₂O | 11.61 | 8.02 | 3.57 | 12.59 | 11.3 | 11.3 | 3.52 |
| K₂O | 6.07 | 1.34 | 8.5 | 3.58 | 3.82 | 3.82 | 5.14 |
| MgO | 0 | 0 | 6.56 | 3.25 | 3.25 | 0 | 0.3 |
| CaO | 0.56 | 4.53 | 0 | 0 | 0.12 | 0.12 | 1.63 |
| SrO | 0 | 0.31 | 7.98 | 0 | 0 | 2.0 | 0 |
| BaO | 0 | 0 | 2.22 | 0 | 2.0 | 0 | 1.38 |
| ZnO | 4.0 | 0.4 | 0 | 0 | 0 | 0 | 0 |
| TiO₂ + ZrO₂ | 0 | 0 | 3.41 | 0.66 | 1.23 | 0.66 | 2.68 |
| SnO₂ + CeO₂ | 0.14 | 0.16 | 0.02 | 0.02 | 0.19 | 0.19 | 0.14 |
| F₂ + Cl₂ | 0.1 | 0 | 0.2 | 0.5 | 0.59 | 0.59 | 0 |
| As₂O₃ + Sb₂O₃ + | 0 | 1.0 | 0.05 | 0.35 | 0.33 | 0.33 | 0 |
| P₂O₅ + La₂O₃ | | | | | | | |
| CaO + SrO + ZnO | 4.56 | 5.24 | 7.98 | 0 | 0.12 | 2.12 | 1.63 |
| ΣM₂O/ΣMO* | 31.55 | 1.88 | 0.72 | 4.98 | 2.82 | 7.13 | 2.61 |
| SiO₂/Al₂O₃ | 5.9 | 6.1 | 8.3 | 5.8 | 6.1 | 6.1 | 5.3 |
| α_{20/300} (10⁻⁶/K) | 8.9 | 7.55 | 8.5 | 8.6 | 9.1 | 8.7 | 7.55 |
| Tg, ° C. | 595 | 573 | 655 | 610 | 593 | 579 | 661 |
| SP, ° C. | 812 | 763 | 898 | 852 | 821 | 822 | 884 |
| SP Tg, ° C. | 217 | 190 | 243 | 242 | 228 | 243 | 223 |
| # of surface defects | <10 | <10 | <10 | <10 | <10 | <10 | <10 |
| β-OH, mmol/l | 52 | 51 | 47 | 31 | 26 | 29 | 63 |

*ΣM₂O/ΣMO = (Na₂O + K₂O)/(MgO + CaO + SrO + ZnO)

The water content can be determined by commercial spectrophotometers in the wavelength range from 2500 to 6000 nm using appropriate calibration standards.

FIG. 1 shows a comparison between the infrared spectrum of the glass of example 4 in the above Table I and two comparable glasses of the prior art and compares the water content (β-OH) of the glass substrate according to the invention with the water content of the prior art glasses, which is determined from the infrared measurements in the wavelength range 2500-6000 nm with the OH absorption maximum of water at 2800 nm. The glasses of the prior art include a soda lime glass and a glass according to JP 11-135819A.

The targeted release of alkali metal ions, in particular sodium, homogeneously over time and also in terms of physical location (over the coating area) over the entire semiconductor deposition step is of critical importance in the production of highly efficient solar cells based on compound semiconductors, in particular when additional processing steps, e.g. addition of sodium, are to be dispensed with in order to realise a cost-efficient process.

It has surprisingly been found that this is achieved only by use of substrate glasses which have no physical phase demixing with alkali-rich and low-alkali regions, in contrast to, for example, boron-containing aluminosilicate glasses or low-water aluminosilicates as described in DE 100 05 088, DE 196 16 679, DE 196 16 633. The substrate glass should release Na ions/Na atoms at temperatures around the Tg, which requires increased mobility of the alkali metal ion.

It has surprisingly been found that the mobility of the alkali metal ions in water-containing glasses such as those having the above composition continues to be ensured despite an increased proportion of alkaline earth metal ions which meet the requirement of a high Tg with simultaneously high thermal expansion but hinder the diffusion of the smaller sodium ions in the glass structure. The ion mobility of the sodium ions and their ease of replacement in the glasses of the invention is positively influenced by, in particular, the residual water content in the glass structure, which can be achieved by selection of water-rich raw materials in the crystal lattice, e.g. by means of Al(OH)₃ instead of Al₂O₃ and by means of an oxygen-rich gas atmosphere in the melting process, also known as oxyfuel process. It has astonishingly been found that the ratio of SiO₂/Al₂O₃ found is also necessary for high alkali metal ion mobility.

In the case of substrates which do not display phase demixing but high alkali metal ion mobility, the alkali metal ions can be released homogeneously in terms of physical location over the entire substrate area to the layers lying on top or can diffuse through these. The release of the alkali metal ions does not stop even at higher temperatures, >600° C. In addition, such a substrate displays improved adhesion properties in respect of the functional layers of molybdenum and compound semiconductors deposited thereon. In a high-temperature process, compound semiconductor layers can grow in an ideal manner, i.e. homogeneous crystal growth over the area and, associated therewith, a higher yield can be achieved, and a sufficiently large alkali metal ion reservoir during the deposition process can be ensured.

In a further conditioning step, alkali metal ions in the upper region of the glass substrate can be replaced in a targeted manner, for example K, Li by Na or vice versa. In this way, glasses having different compositions, see Table I, can be conditioned so that they allow release of exactly one species of alkali metal ions which is homogeneous in terms of physical location and over time.

Thin-film solar cells based on compound semiconductors, in particular those produced in a high-temperature step in a corrosive atmosphere, have to have a high corrosion resistance. It has unexpectedly been found that hydrolytic stability of the above-described glasses of <0.5 μg/g of Na₂O considerably reduces the risk of corrosion. The hydrolytic stability is determined in accordance with DIN ISO 719. Here, the substrate glass is milled to a coarse glass powder having a particle size of 300-500 μm and is then placed in hot, demineralized water at 98° C. for one hour. The aqueous solution is then analysed to determine the alkali metal content.

These glasses display, like soda-lime glasses too, a reaction with SO₂/SeO₂, but in contrast to the soda-lime glasses without visible corrosion of the surface as can be seen on cleaning with water. FIG. 2 shows a corroded glass surface (depicted at left; soda-lime substrate glass) in comparison to the uncorroded surface (depicted at right) of a substrate glass as is suitable for a solar cell according to the invention. This effect is due to the high mobility of the sodium ions in the glass lattice which are resupplied from deeper layers under the surface during the reaction with the chalcogenide oxides and also the phase stability of the glass. This makes homogeneous diffusion of the sodium ions to the surface possible and thus prevents a visibly corroded surface.

The stiffness (dimensional stability at high temperatures of >600° C.) can be estimated, inter alia, from the difference SP-Tg (in ° C.). At least 200° C. is necessary in order to allow thinner substrates than the 3-3.5 mm, i.e. <2.5 mm, customary today. This allows, for example, the cooling section after the coating process from >600° C. to room temperature to be significantly reduced, which reduces processing times and capital costs. Thinner substrate glass likewise results in lower materials costs and lower production cost for the substrate glass itself, which reduces the price difference compared to soda-lime glass and thus contributes to better competitiveness of these substrate glasses.

The substrate glass having the above composition was produced and finished in such a way that it has a high dimensional stability at temperatures of >600° C. This dimensional stability can be expressed as the stiffness, which is indicated, inter alia, by the modulus of elasticity of the glasses of >70 kN/mm² and by the large difference between softening point (SP) and glass transition temperature (Tg). It has surprisingly been found that a temperature difference, SP-Tg of ≧200° C., allows a reduction in the substrate glass thickness from 3-3.5 mm as in the prior art to less than 2.5 mm without loss of stiffness of the substrate glass.

This reduction in the substrate glass thickness enables more rapid heat transport through the substrate glass to be achieved, which allows accelerated processing in the semiconductor deposition process and thus savings in the processing time. In particular, the cooling section, for example, can be reduced significantly, which apart from the reduction in the processing time also significantly reduces the capital costs. Thinner substrate glasses likewise mean lower materials and production costs for the substrate glass itself and can lead to a more positive cost balance in the production of the solar cells due to loss-free transport of the substrate glasses including coatings in in-line plants. Bent substrate glass is problematical, for example as process chamber locks, and can lead to a considerable yield loss. In addition, it is a tremendous advantage in the lamination process for the solar cells not to be bent; here too, substrate glass which is not quite planar can lead to a loss in yield.

FIG. 3 shows the influence of the glass components and in particular the influence of the component Al₂O₃ of an aluminosilicate substrate glass on the modulus of elasticity (kN/cm²) (according to http://glassproperties.com).

Apart from the fundamental mobility of the alkali metal ions, the diffusion paths of the layers located above are also of critical importance, for example through the back contact layer into the semiconductor layer. It has astonishingly been found that the avoidance of structural steps and/or fractures in the back contact layer, as is achieved in the invention by, for example, a single-stage back contact layer, is of key importance in this respect.

This is particularly important to ensure a distribution of alkali metal ions which is homogeneous in terms of physical location and over time.

It is known that substrate glass surfaces age with time and lose their originally active surface. It has astonishingly been found that coating the glass surface with a metal film preserves this activity. This applies in particular to coating with tungsten, silver, vanadium, tantalum, chromium, nickel, particularly preferably molybdenum. The metal film has a thickness of from 0.2 to 5 μm, particularly preferably from 0.5 to 1 μm, and a conductivity of from 0.6×10⁵ to 2×10⁵ ohm.cm, particularly preferably from 0.9×10⁵ to 1.4×10⁵ ohm.cm.

Furthermore, it was astonishingly found that, owing to the absence of any visible phase separation (as described above) in the high-temperature-stable substrate glasses of the above composition together with a corresponding stability against crystallization, particularly good adhesion of the metal back contact to the substrate glasses was obtained. Adhesion problems which are frequently observed in the case of soda-lime glasses, for example detachment of the layer at some places, also referred to as “chocolate paper”, were not observed in the case of substrates coated according to the invention with the metal back contact, particularly preferably when the metal back contact is a single-layer system having few or no structural steps. It has surprisingly been found that the absence of any visible phase separation in the above-mentioned substrate glasses also leads to excellent adhesion of the CIGS layer to the metal back contact compared to conventional substrates. In the sequential process, voids at the interface of CIGS layer and back contact, referred to as “underground garages”, have frequently been found on soda-lime glass, with only small islands serving to effect adhesion. In contrast, full-area adhesion has been found in the case of the solar cells of the invention based on the above-mentioned substrate glasses, in particular in conjunction with a high-temperature step, which can be attributable to the homogeneous release of sodium ions in terms of physical location and over time from the substrate glasses and the homogeneous diffusion in terms of physical location and over time of these through the metal back contact layer due to the avoidance of structural steps.

A substrate glass having a Tg which is higher than that of standard soda-lime glass allows higher processing temperatures during semiconductor deposition. It is known that higher deposition temperatures during chalcopyrite formation can lead to a distinct minimization of crystal defects down to below the detection limit, e.g. the CuAu order. This applies particularly to the above-described sequential process. The semiconductor layers of the solar cells of the invention having a substrate glass of the above-stated composition and in which a semiconductor layer has been deposited at temperatures of >600° C. surprisingly meet the requirement for high crystallinity and thus fewer defects. This can be seen from the Raman spectra in FIG. 4. FIG. 4 shows the A1 mode of a CIGS absorber layer deposited according to the invention at high temperatures and the A1 mode of a CIGS layer deposited on soda-lime glass. The lower width at half height for the solar cell according to the invention is a direct measure of better crystal quality and thus fewer defects. In the case of the CIGS layer according to the invention deposited in a high-temperature step (T>550° C.) on a substrate glass having the composition described, the mode displays a lower width at half height than in the case of a CIGS layer produced by the conventional process on a soda-lime substrate glass (greater width at half height).

It has astonishingly been found that higher processing temperatures also make more rapid processing possible. Processes at the crystal formation front in particular proceed more rapidly and, for example, the incorporation of elements on the appropriate sites in the crystal is accelerated. In the case of sequential processing, a significant mechanism is the diffusion of the individual atoms to the surface at which the reactions with the chalcogen atoms take place. A higher temperature results in a higher diffusion speed of the elements to the reaction surface and thus more rapid transport of the elements required for crystal formation to the crystallization front. Typical heating ramps are in the range from 5 to 10 K/s, at hold times at maximum temperature of about 5 minutes and typical cooling ramps in the range from 3 to 4 K/s. It has surprisingly been found that heating ramps of >10 K/s and in particular cooling profiles of >4 K/s, particularly preferably >5 K/s could be achieved on the basis of the substrate glasses having the above composition. Furthermore, it was found that, despite accelerated heating and cooling ramps and a maximum temperature of significantly greater than 550° C., no outgassing from the substrate glasses having the above composition was found, in contrast to conventional substrate glasses such as soda-lime glasses.

### BRIEF DESCRIPTION OF THE DRAWING

The objects, features and advantages of the invention will now be illustrated in more detail, with reference to the accompanying figures in which:

FIG. 1 shows a comparison of infrared spectra of an example of the glass according to the present invention and two glasses of the prior art, from which the stated water contents were determined;

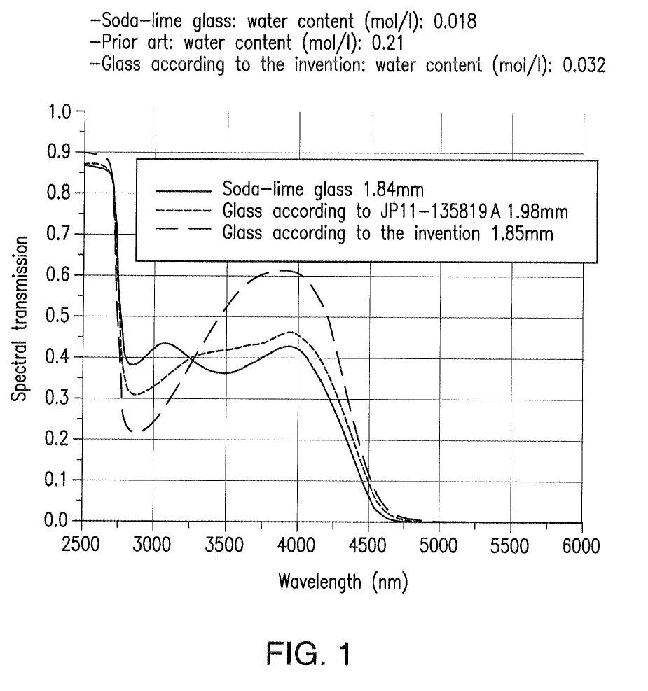

FIG. 2 illustrates a comparison between a corroded soda line glass substrate of the prior art (left hand side) and an uncorroded glass substrate according to the invention (right hand side);

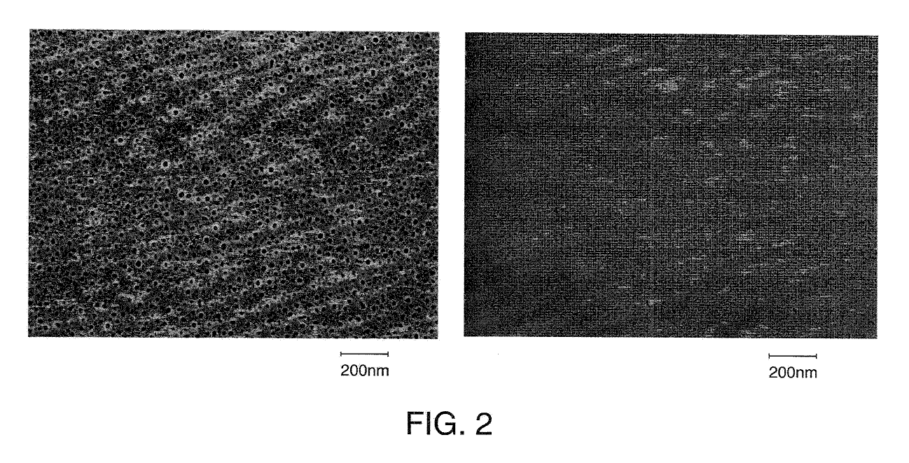

FIG. 3 is a graphical illustration showing the dependence of the modulus of elasticity (kN/cm²) of an aluminosilicate glass on the mol % of various oxide components, and in particular shows the influence of the component Al₂O₃ on the modulus of elasticity (kN/cm²), which is published on the Internet at http://glassproperties.com;

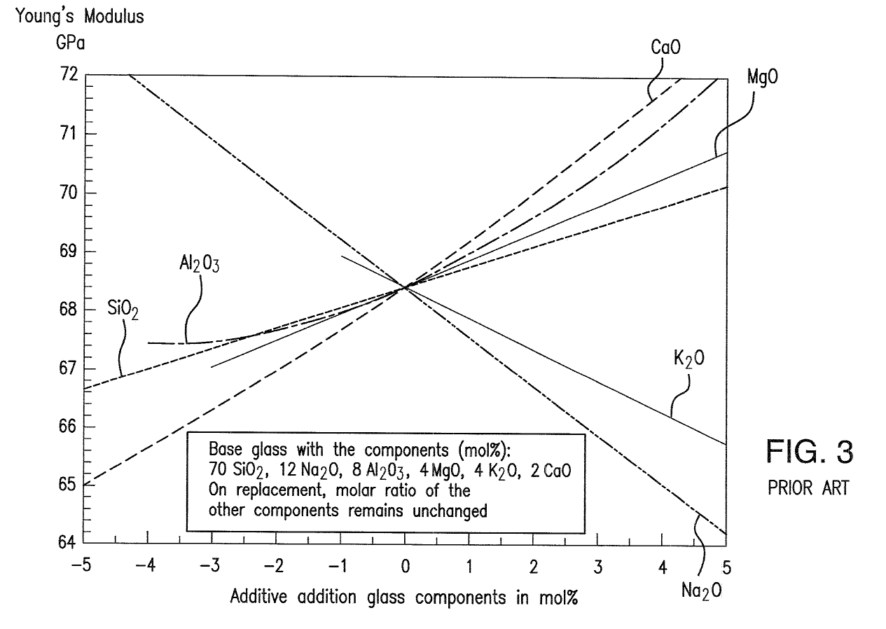

FIG. 4 is a graphical illustration of the dependence of spectral intensity on wavelength (cm⁻¹) in Raman spectra of a CIGS layer deposited on a soda-lime glass of the prior art and of a CIGS layer deposited according to the invention at high temperatures, which show the better crystal quality and thus fewer defects according to the present invention;

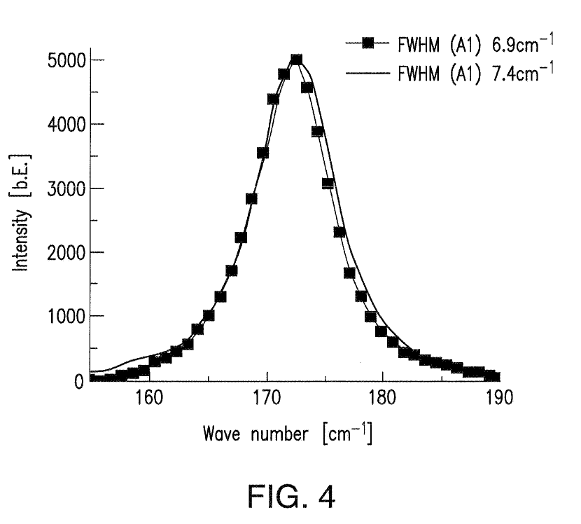

FIG. 5 is a scanning electron micrograph of a cross section through the zonal structure of a multilayer molybdenum coating (three-layer process sequence) on a substrate glass (left-hand side of the micrograph) in a solar cell according to the prior art, in which the three steps in the molybdenum layer are visible here (in the middle of micrograph); and

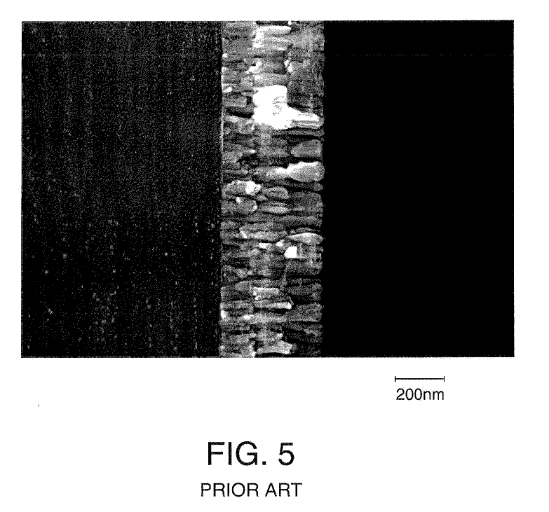

FIG. 6 is a scanning electron micrograph of a cross section through the columnar, stepless structure of a molybdenum layer in a solar cell according to the invention, which has been applied by means of a single-layer process.

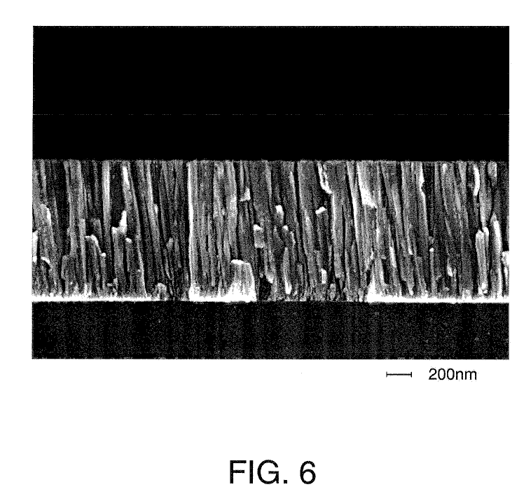

While the invention has been illustrated and described as embodied in a thin-film solar cell and process for producing a thin-film solar cell, it is not intended to be limited to the details shown, since various modifications and changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention.

What is claimed is new and is set forth in the following appended claims.

We claim:

1. A thin-film solar cell comprising at least one Na₂O-containing multicomponent substrate glass, wherein the substrate glass is not phase demixed and has a content of β-OH of from 25 to 80 mmol/l.

2. The thin-film solar cell as defined in claim 1, wherein the substrate glass
has a glass transition temperature Tg of greater than 550° C., and/or
has a coefficient of thermal expansion α_{20/300} of greater than 7.5×10⁻⁶/K in a temperature range from 20° C. to 300° C., and/or
contains less than 1% by weight of B₂O₃, less than 1% by weight of BaO, and less than a total of 3% by weight of CaO+SrO+ZnO, and/or
has a molar ratio of Na₂O+K₂O to MgO+CaO+SrO+BaO of greater than 0.95, and/or
contains SiO₂ and Al₂O₃ and has a molar ratio of SiO₂ to Al₂O₃ of less than 8.8.

3. The thin-film solar cell as defined in claim 1, wherein the substrate glass has a glass transition temperature Tg that is greater than 600° C.

4. The thin-film solar cell as defined in claim 1, wherein the substrate glass has a coefficient of thermal expansion α_{20/300} that is from 8.0×10⁻⁶/K to 9.5×10⁻⁶/K in a temperature range from 20° C. to 300° C.

5. The thin-film solar cell as defined in claim 1, wherein the substrate glass contains SiO₂ and Al₂O₃ and has a molar ratio of SiO₂ to Al₂O₃ is less than 7.

6. The thin-film solar cell as defined in claim 1, which is planar, curved, spherical, or cylindrical.

7. A process of producing a thin-film solar cell, said process comprising the steps of:
a) providing an Na₂O-containing multicomponent substrate glass having a content of β-OH of from 25 to 80 mmol/l, wherein the substrate glass is not phase demixed;
b) applying a metal layer to the substrate glass, said metal layer forming an electrical back contact of the thin-film solar cell;
c) applying an intrinsically p-conducting polycrystalline layer of a compound semiconductor material, said applying including at least one high-temperature step at a temperature of >550° C.; and
d) applying a pin junction.

8. The process as defined in claim 7, wherein said compound semiconductor material is a CIGS compound semiconductor material.
